(19) United States
(12) Patent Application Publication
(10) Pub. No.: US 2005/0237831 A1
(43) Pub. Date: Oct. 27, 2005

(54) Electro-optical device, precharge method thereof, image processing circuit, and electronic apparatus

(75) Inventor: Kenya Ishii, Fujimi-cho (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/090,025

(22) Filed: Mar. 28, 2005

(30) Foreign Application Priority Data
Apr. 22, 2004 (JP) 2004-126507

(51) Int. Cl. G11C 29/00

(52) U.S. Cl. 365/201

(57) ABSTRACT

Aspects of the invention can provide an electro-optical device that can include a plurality of pixels disposed at the intersections of a plurality of scanning lines and a plurality of data lines which are divided into blocks of N data lines (N being a natural number greater than 2), the pixels respectively having gray-scale levels corresponding to voltages applied to the data lines when the scanning lines are selected, a scanning line driving circuit can select the scanning lines in selection periods separated by a time gap, a precharge voltage generation circuit that can generate a plurality of precharge voltages to precharge the plurality of data lines, the precharge voltage generation circuit generating the precharge voltages so that a precharge voltage corresponding to one of N data lines belonging to each block is different from precharge voltages corresponding to the other data lines in each block, N image signal lines that respectively correspond to the data lines in each the block, the image signal lines applying voltages corresponding to gray-scale levels of pixels corresponding to the data lines in each block in the selection period, and at the same time applying the plurality of precharge voltages generated by the precharge voltage generation circuit in precharge periods other than the selection period, and a data line driving circuit that can apply the voltages applied to the image signal lines to the data lines in each block in the selection period, and at the same time applies the voltages to the data lines in the precharge period.

### BACKGROUND

Aspects of the invention can relate to an electro-optical device using an electro-optical material, such as liquid crystal. More particularly, the invention can relate to technologies in which data lines are precharged prior to applying voltages corresponding to gray-scale levels to pixels disposed at intersections of scanning lines and the data lines.

In related art electro-optical devices, such as liquid crystal devices, there has been proposed a construction in which image signals applied to a plurality of image signal lines are supplied to pixels by sampling the images signals in data lines. However, in this related art construction, due to the differences in the electrical properties (for example, resistance value) of the image signal lines wired on a substrate, in the case in which the pixels are displayed with a common gray-scale level, the gray-scale levels that are actually displayed are different in the horizontal direction (the extending direction of the scanning lines), which results in display unevenness. Particularly, in a construction in which the image signals are sampled in the image signal lines on a block basis and a plurality of data lines are divided into blocks of N data lines, the data line located at the end of each block and the data line in the neighboring block are capacitively coupled. As a result, there can occur a case in which the voltage, which is applied to the data line located at the end of each block according to the image signal, varies due to the voltages applied to the neighboring data line. In this case, error between the gray-scale levels of one column of pixels corresponding to the data line located at the end of each block and the intended gray-scale level is pronounced compared to the pixels corresponding to other data lines. Accordingly, there occurs a case in which lines appear in the vertical direction (the extending direction of the data lines) at the boundary of the blocks, resulting in display unevenness.

In this related construction, in order to prevent or reduce the display unevenness from appearing, it is necessary to perform a process of correcting the image signals as well as a process of expanding one channel of the image signals N times and then elongating them on the time axis by a factor of N, or a process of properly amplifying the image signals while alternately inverting the polarity of the image signals. However, in this case, there is a problem in that the construction of a circuit for executing these processes becomes complicated and the circuit becomes bulky.

### SUMMARY

An advantage of the invention is that it prevents or reduces display unevenness without the need for a complicated correction process for image signals. Aspects of the present invention can provide an electro-optical device, including a plurality of pixels, that is disposed at the intersections of a plurality of scanning lines and a plurality of data lines and a plurality of data lines which are divided into blocks of N data lines (N is a natural number greater than 2), and the pixels respectively having gray-scale levels corresponding to voltages applied to the data lines when the scanning lines are selected, a scanning line driving circuit that selects the scanning lines in selection periods (e.g., “horizontal valid scanning period” in an exemplary embodiment to be described below) separated by a time gap, a precharge voltage generation circuit that generates a plurality of precharge voltages to precharge the plurality of data lines, the precharge voltage generation circuit generating the precharge voltages so that a precharge voltage corresponding to one of N data lines belonging to each block is different from precharge voltages corresponding to the other data lines in each block, N image signal lines that respectively correspond to the data lines in each the block, the image signal lines applying voltages corresponding to gray-scale levels of pixels corresponding to the data lines in each block in the selection period, and at the same time, applying the plurality of precharge voltages generated by the precharge voltage generation circuit in precharge periods (for example, “horizontal retracing period” in an embodiment to be described later) different from the selection period, and a data line driving circuit that applies the voltages applied to the image signal lines to the data lines in each block in the selection period, and at the same time, applies the voltages to the data lines in the precharge period. This kind of the electro-optical device can be typically adopted as means for displaying an image in a variety of electronic devices. Further, the electro-optical device can be a device that outputs modulated light by way of the action of an electro-optical material. The electro-optical material can be a material whose optical properties such as transmittance or brightness vary depending upon electrical energy such as current or voltage. An example of the electro-optical material typically includes liquid crystal whose transmittance varies according to an applied voltage. The present invention can be applied to even an electro-optical device using an electro-optical material other than liquid crystal (for example, OLED (Organic Light Emitting Diode) devices, such as organic EL (Electroluminescent)).

According to this exemplary construction, since each data line is precharged with a precharge voltage in the precharge period, it is possible to reduce the time taken to shift a voltage of each data line to a predetermined voltage (a voltage depending upon a gray-scale level of each pixel) in the selection period. Moreover, a plurality of precharge voltages can be generated in such a way that a precharge voltage used to precharge one of the plurality of the data lines and precharge voltages used to precharge the remaining data lines are different. Thus, display unevenness can be reduced or removed by correcting error in voltages that are applied to the data lines through the precharge voltages. For example, in the case in which a voltage actually applied to a particular data line is lower than a desired voltage (a voltage depending on a gray-scale level of a pixel), a voltage applied to each pixel through the particular data line can be made to reach the desired voltage (ideally identically) by generating a precharge voltage to be applied to the data line, which is higher than a precharge voltage of other data lines. Furthermore, a process for correcting error in the voltages applied to the data lines needs not to be performed on image signals. It is thus possible to simplify the construction of a circuit for performing a predetermined process on the image signals and to prohibit the circuit from becoming bulky, compared to the construction in the related art.

However, a data line, which is located at the downstream end in a direction where a block is selected, among an N data lines that belong to each of the blocks can be capacitively coupled with each of data lines of a block that is selected next time. Thus, in a construction wherein a voltage depending on a gray-scale level of each of pixels (hereinafter, referred to as “gray-scale voltage”) is applied to each of a plurality of data lines on a block basis, the degree of a difference between a voltage applied to one data line located at the downstream end in the block selection direction and a gray-scale voltage is greater than the degree of a difference between a voltage applied to other data lines and the gray-scale voltage. As a result, display unevenness occurs, which results in generation of error in the gray-scale level of the pixel corresponding to the data line located at the end of each block can be generated. In view of this, in a preferred aspect of the invention, the data line driving circuit sequentially selects the plurality of blocks in the order of their arrangement in the selection period, and at the same time, supplies the voltages applied to the image signal lines to the data lines of the selected blocks. Further, the precharge voltage generation circuit generates the precharge voltages so that the precharge voltage of a data line that is located at the downstream end of a direction in which the blocks are selected, among the N data lines belonging to each block, is higher than the precharge voltages of other data lines in each block. In accordance with this construction, since error in voltages applied to data lines, which is caused due to capacitive coupling among neighboring data lines, can be corrected, display unevenness can be prohibited.

Furthermore, due to various factors, such as variation in electrical characteristics among image signal lines other than capacitive coupling among neighboring data lines, there occurs a case in which the small and large of a difference between a voltage actually applied to each data line and a gray-scale voltage are irregular every data line. Even in this case, if the precharge voltage generation circuit is constructed to generate different voltages as N precharge voltages corresponding to data lines that belong to each of the blocks, error in voltages applied to the data lines can be corrected with good accuracy. At this time, the large and small of error in the voltages applied to the data lines can depend upon a direction that selects each of blocks. For instance, in a construction wherein all data lines are charged with a common precharge voltage or a construction in which no precharge is performed on any data line, there occurs a case in which an actual applied voltage (particularly, an absolute value of the applied voltage) is lowered in a data line located in the downstream of the block selection direction among an N data lines that belong to each of the blocks.

In view of this, in another aspect of the invention, the data line driving circuit sequentially selects the plurality of blocks in the order of their arrangement in the selection period, and at the same time, supplies the voltages applied to the image signal lines to the data lines of the selected blocks. Further, the precharge voltage generation circuit generates the precharge voltages so that the precharge voltage of a data line that is located at the downstream end of a direction in which the blocks are selected, among the N data lines belonging to each block, is higher than the precharge voltages of other data lines in each block. In accordance with this construction, precharge voltages can be selected on a data line basis in such a way to correspond a difference in voltages applied to the data lines. Therefore, error of voltages applied to the data lines can be prohibited with good accuracy.

The invention can be conceived as a method for precharging each of data lines of an electro-optical device. The invention provides a method of precharging a plurality of data lines before a plurality of scanning lines is selected in an electro-optical device, in which a plurality of pixels are disposed at the intersections of the plurality of the scanning lines and the plurality of the data lines, in which the data lines are divided into blocks of N data lines (N is a natural number greater than 2), becomes brightness corresponding to voltages applied to the data lines when the scanning lines are selected in selection periods separated by a time gap, the method including generating precharge voltages, in which the precharge voltage corresponding to one of N data lines belonging to each block is different from the precharge voltages corresponding to the other data lines in each block, applying voltages corresponding to gray-scale levels of pixels corresponding to the data lines in each block to N image signal lines corresponding to the data lines in each block, on a block basis, in the selection period, and at the same time, applying the plurality of precharge voltages in precharge periods other than the selection period, and applying the voltage applied to the image signal lines to the data lines in each block in the selection period, and at the same time, applying the voltages to the data lines in the precharge period. In accordance with this method, based on the same reason as that described with reference to the electro-optical device according to the invention, it is possible to prevent or reduce display unevenness without a complex correction process on image signals.

Further, the invention can be conceived as an image processing circuit used in an electro-optical device. The exemplary image processing circuit for an electro-optical device can include a plurality of pixels disposed at the intersections of a plurality of scanning lines and a plurality of data lines which are divided into blocks of N data lines (N is a natural number greater than 2), and the pixels respectively having gray-scale levels corresponding to voltages applied to the data lines when the scanning lines are selected, a scanning line driving circuit that selects the scanning lines in selection periods separated by a time gap, N image signal lines that respectively correspond to the data lines in each block, a data line driving circuit that supplies voltages applied to the image signal lines to the data lines, on a block basis, in the selection period, and at the same time, applies the voltages to the data lines in precharge periods that are different from the selection period, an image signal output circuit that generates N image signals having different voltages corresponding to gray-scale levels of pixels corresponding to the data lines in each block, on a block basis, a precharge voltage generation circuit that generates a plurality of precharge voltages to precharge the plurality of data lines, the precharge voltage generation circuit generating the precharge voltages so that a precharge voltage corresponding to one of N data lines belonging to each block is different from precharge voltages corresponding to the other data lines in each block, and a selection circuit that supplies the image signals generated by the image signal output circuit to the image signal lines, in the selection period, and at the same time, supplies the precharge voltages generated by the precharge voltage generation circuit to the image signal lines corresponding to the data lines precharged with the precharge voltages, in the precharge period. In accordance with this image processing circuit, based on the same reason as that described with reference to the electro-optical device according to the invention, it is possible to prevent or reduce display unevenness without a complex correction process on image signals.

### BRIEF DESCRIPTION OF THE DRAWINGS

The invention will be described with reference to the accompanying drawings, wherein like numbers reference like elements, and wherein:

FIG. 1 is a block diagram showing a configuration of a liquid crystal device according to an exemplary embodiment of the invention;

FIG. 2 is a circuit diagram illustrating an electrical configuration of a display panel in the liquid crystal device according to the exemplary embodiment of the invention;

FIG. 3 is a circuit diagram illustrating the configuration of each of pixels in the display panel according to the exemplary embodiment of the invention;

FIG. 4 shows a timing chart for explaining an operation of the liquid crystal device according to the exemplary embodiment of the invention;

FIGS. 5(a) and 5(b) are views for explaining a voltage value of each of precharge voltages;

FIGS. 6(a) and 6(b) are views for explaining the level of each of precharge voltages according to a modification example;

FIG. 7 is a view for explaining the level of each of precharge voltages according to another modification example of FIG. 5;

FIG. 8 is a block diagram showing a configuration of a liquid crystal device according to another exemplary embodiment of the invention; and

FIG. 9 is a view illustrating a configuration of a projector, which is an exemplary electronic device according to the invention.

### DETAILED DESCRIPTION OF EMBODIMENTS

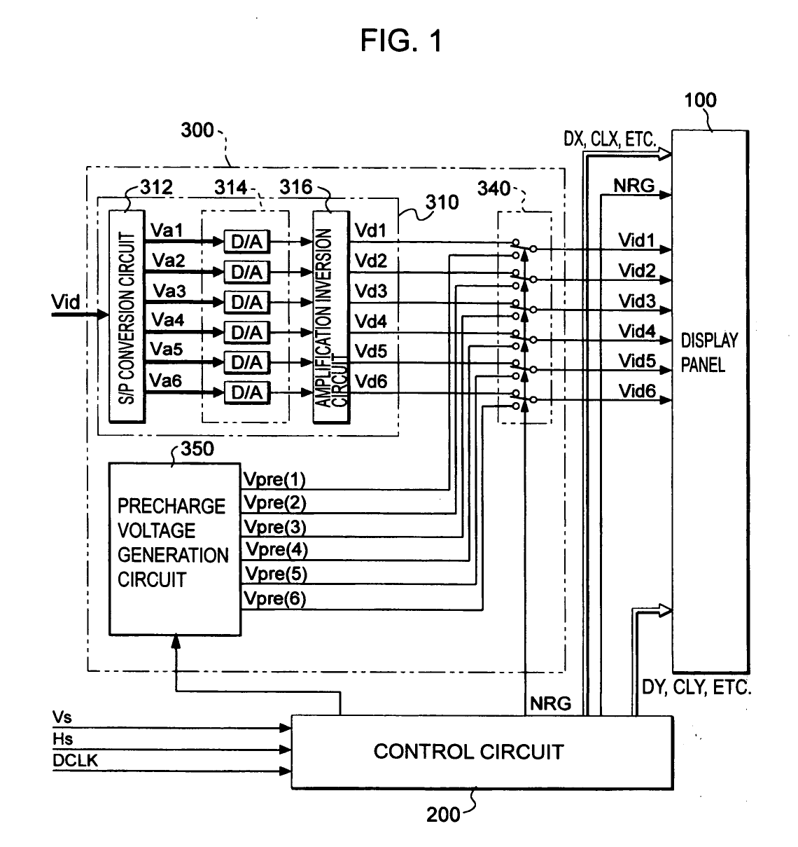

Exemplary embodiments in which the invention is applied to a liquid crystal device using liquid crystal as an electro-optical material will be first described. FIG. 1 is a block diagram showing the configuration of a liquid crystal device according to an exemplary embodiment of the invention. Referring to FIG. 1, the liquid crystal device can include a display panel 100, a control circuit 200 and an image processing circuit 300. Of them, the control circuit 200 serves to generate control signals (timing signals, clock signals, etc.) for controlling the respective components of the liquid crystal device based on a vertical scanning signal Vs, a horizontal scanning signal Hs and a dot clock signal DCLK, which are supplied from an upper level apparatus such as a central processing unit (CPU) of an electronic device in which the liquid crystal device is mounted.

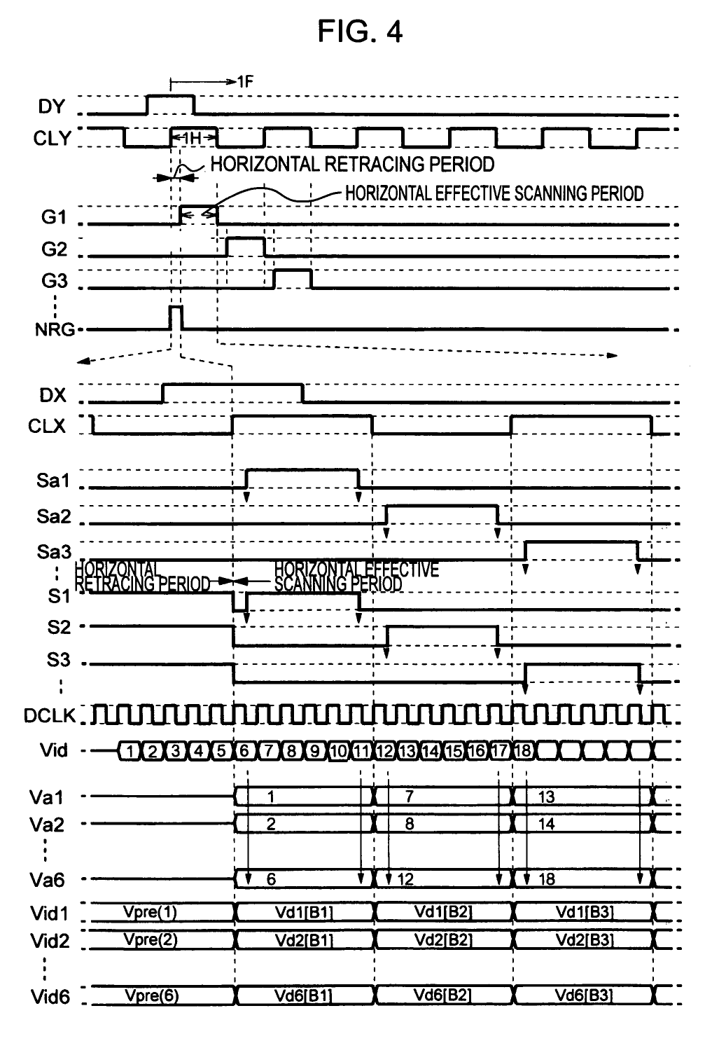

The image processing circuit 300 is a circuit for processing image data Vid that are supplied from the upper level apparatus to be signals suitable for the supply to the display panel 100. The image processing circuit 300 includes an image signal output circuit 310, a selector (in the present invention, a selection circuit) 340, and a precharge voltage generation circuit 350. Among them, the image signal output circuit 310 is a circuit for outputting N channels (N is a given natural number greater than 2, but it is assumed that N=6 in the embodiment) of image signals Vd1, Vd2 . . . , Vd6, for designating gray-scale levels (brightnesses) of respective pixels of the display panel 100. The image signal output circuit 310 includes a serial to parallel (S/P) conversion circuit 312, a digital to analog (D/A) converter group 314, and an amplification inversion circuit 316. To the image signal output circuit 310 is serially supplied the image data Vid from the upper level apparatus in synchronism with the vertical scanning signal Vs, the horizontal scanning signal Hs and the dot clock signal DCLK (i.e., in synchronism with a vertical scan and a horizontal scan). The image data Vid are data for designating the gray-scale levels of the pixels of the display panel 100 as a digital value on a pixel basis. The S/P conversion circuit 312 shown in FIG. 1 is a circuit that outputs image data Va1, Va2 . . . , Va6 by extending signals of each of channels on a time axis by six times (serial-parallel conversion), while distributing one channel of the image data Vid into 6 channels of image data, as shown in FIG. 4. In this case, the reason why the serial-parallel conversion is performed is that it allows a sampling circuit 150 (to be described later) to secure sufficient time to sample and hold the image signals Vd1 to Vd6. Meanwhile, the D/A converter group 314 has a D/A converter every channel of image data, and serves to convert the image data Va1 to Va6 into analog image signals each having voltages depending upon the gray-scale levels of the pixels.

The amplification inversion circuit 316 can be a circuit for converting the polarity of each of the image signals, which are output from the D/A converter group 314, amplifying the signals, and outputting the amplified signals as image signals Vd1, Vd2, . . . , Vd6. In this case, the polarity inversion in the embodiment refers to a process of alternately switching the voltage level of the image signal from the positive polarity to the negative polarity, and vice versa on the basis of a predetermined voltage Vc (this is typically a voltage that becomes the center of the image signal, and more particularly, this voltage is almost the same as a voltage Lccom applied to a counter electrode). A target image signal whose polarity will be inversed is properly selected depending upon whether a mode where a voltage is applied to each of pixels is [1 ] a mode where the polarity is inversed on a scanning line basis (so-called row inversion), [2] a mode where the polarity is inversed on a data line basis (column inversion), [3] a mode where the polarity is inversed on a neighboring pixel basis (so-called pixel inversion) or [4] a mode where the polarity is inversed on a screen basis (frame) (so-called frame inversion). In the exemplary embodiment, however, the construction employing the row inversion [1] is illustrated as an example for convenience of explanation. It is also to be noted that the sequence of serial-parallel conversion, D/A conversion, polarity inversion and amplification is not limited to the above example of FIG. 1, but can be changed arbitrarily.

The precharge voltage generation circuit 350 shown in FIG. 1 is a circuit for generating six kinds of precharge voltages Vpre(1), Vpre(2) . . . , Vpre(6), which correspond to the number of channels of the image signal Vdk (k is a natural number from 1 to 6). Meanwhile, the selector 340 is a circuit that selects any one of the image signals Vd1 to Vd6 output from the image signal output circuit 310 and the precharge voltages Vpre(1) to Vpre(6) output from the precharge voltage generation circuit 350, and then applies them to the display panel 100 as signals Vid1 to Vid6. Furthermore, description on a detailed operation of each of the precharge voltage generation circuit 350 and the selector 340 will be described below.

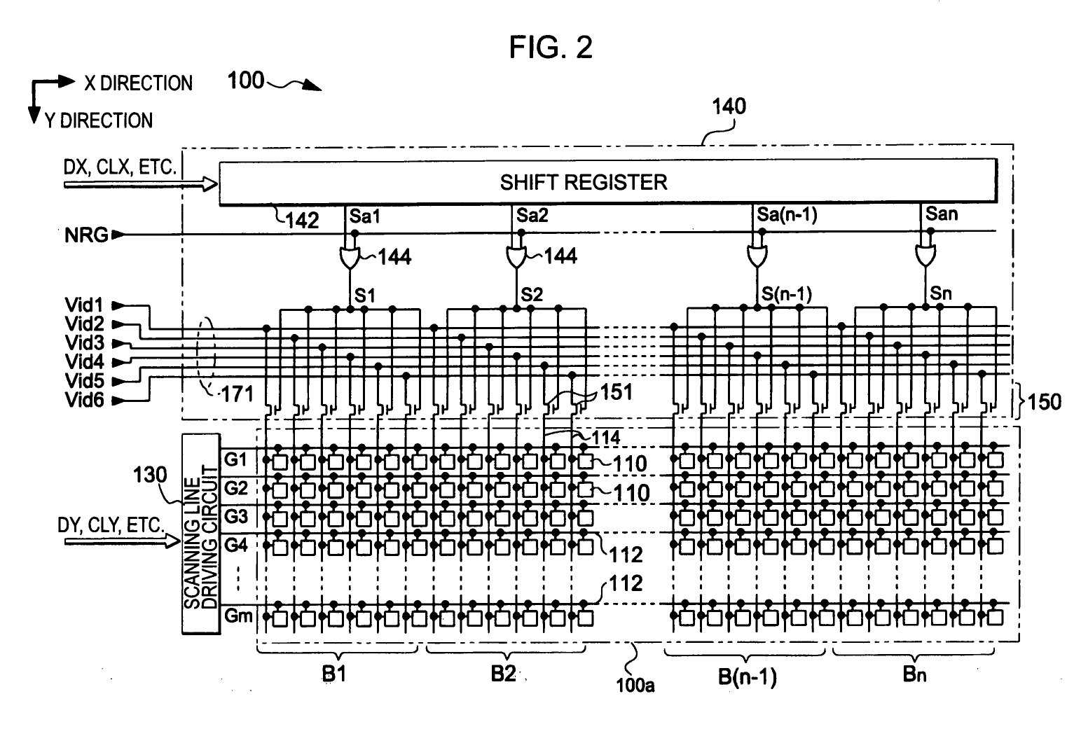

The construction of the display panel 100 will now be described with reference to FIG. 2. The display panel 100 has a construction in which an element substrate and a counter substrate having counter electrodes formed therein are coupled with a predetermined gap therebetween, and the gap is filled with liquid crystal. At this time, a total m (m is a natural number greater than 2) number of scanning lines 112 that extend in a X direction, and a total 6n (n is a natural number great than 2) of data lines 114 that extend in a Y direction are formed in a display region 100a defined in the element substrate, as shown in FIG. 2. As shown in FIG. 2, the total 6n data lines 114 are divided into total n blocks B1, B2, . . . , Bn on the basis of 6 (N number) corresponding to the channel number of the image signal Vdk.

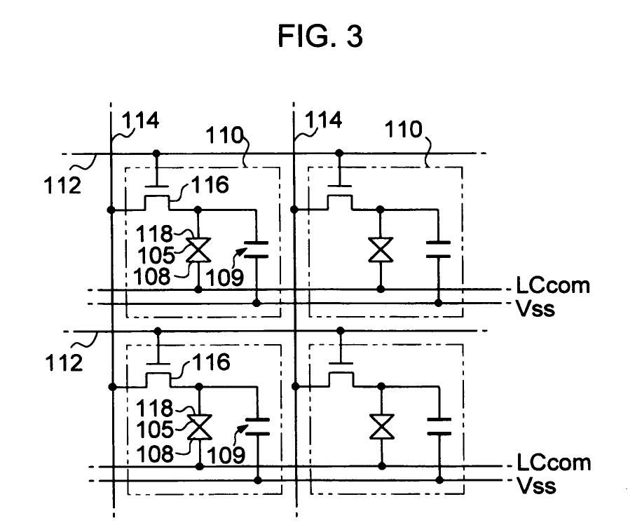

Each of pixels 110 is arranged at the intersection of each of the scanning lines 112 and each of the data lines 114. Accordingly, the plurality of the pixels 110 has the matrix form of ‘m’ row X ‘6n’ column along the X direction and Y direction, and is arranged in the display region 100a. Each of the pixels 110 includes a thin film transistor (hereinafter, referred to as “TFT”) 116 connected to the scanning line 112 and the data line 114, and a pixel electrode 118 connected to the TFT 116, as shown in FIG. 3. Each TFT 116 has a gate electrode connected to the scanning line 112, a source electrode connected to the data line 114, and a drain electrode connected to the pixel electrode 118. Meanwhile, each of the pixel electrodes 118 has a generally rectangular form. A liquid crystal layer 105 is intervened between the pixel electrode 118 and a counter electrode 108, which is formed in the counter substrate and is kept to a predetermined voltage Lccom. Furthermore, a liquid crystal capacitor is formed by the liquid crystal layer 105, which is disposed between the pixel electrode 118 and the counter electrode 108. Furthermore, in the present exemplary embodiment, the pixel 110 has a storage capacitor 109 disposed parallel to a corresponding liquid crystal capacitor in order to prevent leakage in the liquid crystal capacitor. One end of the storage capacitor 109 is connected to the pixel electrode 118 (i.e., the drain electrode of the TFT 116), whereas the other end of the storage capacitor 109 is commonly connected to a low-level voltage side (ground voltage) Vss in all of the pixels 110. The other end of the storage capacitor 109 is not limited to the voltage Vss, but can be kept to a given voltage (for example, the voltage Lccom, a high level voltage of a driving circuit, etc.).

As shown in FIG. 2, driving circuits, such as the scanning line driving circuit 130, to which the scanning lines 112 are each connected or the data line driving circuit 140 to which the data lines 114 are each connected are disposed around the display region 100a. Of them, the scanning line driving circuit 130 is a circuit for sequentially selecting an m number of the scanning lines 112. In the exemplary embodiment, the scanning line driving circuit 130 has a shift register of m bits, which correspond to a total number of the scanning lines 112, and sequentially outputs scanning signals G1, G2 . . . , Gm, which sequentially become an active level in each horizontal scanning period, to the scanning lines 112, respectively. This will be below described in more detail.

The scanning line driving circuit 130 serves to sequentially shift a transmission start pulse DY, which is supplied from the control circuit 200 at the beginning of a vertical scanning period, in synchronism with a clock signal CLY (a clock signal having a pulse width corresponding to one horizontal scanning period) that is supplied from the control circuit 200, as shown in FIG. 4, shape a waveform of the shifted signal in such a way that a pulse width of the signal becomes narrow, and then output the shaped signal to the scanning line 112 of an i-th row as scanning signal Gi (i is an integer that satisfies the relationship 1≦i≦m). Thereinafter, a period where the scanning signal Gi of each horizontal scanning period (1H) becomes an active level, as shown in FIG. 4, will be referred to as horizontal valid scanning period, and a period immediately before the period (i.e., a period from the start point of the horizontal scanning period until the scanning signal Gi becomes an active level) will be referred to as horizontal retracing period. In the horizontal valid scanning period, if the scanning signal Gi becomes an active level, all the TFTs 116 of one row (6n in total), which are connected to the i-th row scanning line 112, are turned on.

As shown in FIG. 2, a total of six image signal lines 171 corresponding to the channel number of the image signals Vd are formed in the element substrate of the display panel 100. The signals Vid1 to Vid6 that are input from the selector 340 of the image processing circuit 300 to the display panel 100 are transmitted by the image signal lines 171, respectively That is, the signal Vid1 is applied to the first image signal line 171, and the signal Vid2 is applied to the second image signal line 171. The data line driving circuit 140 shown in FIG. 2 is a circuit for sampling the signals Vid1 to Vid6 applied to the image signal lines 171 in the data lines 114, respectively. The data line driving circuit 140 includes a shift register 142, a plurality of OR circuits 144 and a sampling circuit 150. Among them, the shift register 142 is a shift register of n bits corresponding to a total number of the blocks B1, B2, . . . , Bn, which are formed by dividing the data lines 114. As shown in FIG. 4, the shift register 142 sequentially shifts transmission start pulses DX, which are supplied at the beginning of each horizontal valid scanning period, in synchronism with a clock signal CLX, shapes waveforms of the shifted signals in such a manner that pulse widths thereof become narrow, and then outputs the shaped signals as signals Sa1, Sa2 . . . , San. The signal Saj (j is an integer that satisfies the relationship 1≦j≦n) that is output from the shift register 142 corresponds to a j-th block Bj starting from the left side in FIG. 2, among the total n blocks B1 to Bn.

As shown in FIG. 2, a total n number of OR circuits 144, which corresponds to a total number of the blocks B1 to Bn, are disposed at the rear side of the shift register 142 so that they correspond to output terminals of the shift register 142, respectively. To one of the input terminals of each of the OR circuits 144 are input the signals Saj output from the shift register 142, and to the other of the input terminals of each of the OR circuits 144 is input a signal NRG output from the control circuit 200. In this construction, when viewed from the left side of FIG. 2, a j-th OR circuit 144 outputs signals corresponding to a logical sum of the signals Saj output from the shift register 142 and the signal NRG as sampling signals Sj (S1, S2 . . . , Sn). In this case, the signal NRG is one, which becomes an active level (H level) in a horizontal retracing period of each horizontal scanning period, but becomes an inactive level (L level) in a horizontal valid scanning period, as shown in FIG. 4. As such, the sampling signals S1 to Sn become an active level (H level) when the signal NRG shifts to an active level in the horizontal retracing period, whereas the sampling signals S1 to Sn sequentially become an active level (H level) according to the level of each of the signals Sa1 to San in the horizontal valid scanning period.

The sampling circuit 150 is then a circuit that samples the signals Vid1 to Vid6, which are received from the image processing circuit 300 through the six image signal lines 171, according to the sampling signals S1 to S6 through the data lines 114. The sampling circuit 150 has a total 6n number of sampling switches 151, which corresponds to a total number of the data lines 114. A drain electrode of each of the sampling switches 151 is connected to the data line 114, whereas a gate electrode of each of the six sampling switches 151 each connected to the data lines 114, which belong to each of the blocks Bj, is commonly connected to the output terminal of the j-th OR circuit 144 located at the prior-stage. In addition, a source electrode of each of the six sampling switches 151, which corresponds to each of the blocks Bj, is connected to each of the image signal lines 171. That is, a source electrode of each of the n number of the sampling switches 151, which is connected to the first data line 114 from the left side in each of the blocks B1, B2 . . . , Bn, is connected to the image signal line 171 from which the signal Vid1 is applied.

A source electrode of each of a total n number of the sampling switches 151, which is connected to the second data line 114, is connected to the image signal line 171 from which the signal Vid2 is applied. A source electrode of each of the sampling switches 151, which is connected to the sixth data line 114 located at the end of each block Bj is connected to the image signal line 171 from which the signal Vid6 is applied. In this construction, if each of the sampling signals Sj shifts to an active level, the six sampling switches 151 corresponding to the blocks Bj are turned on at the same time, so that the data lines 114 and the image signal lines 171 that belong to corresponding blocks Bj become conductive. This will be below described in more detail. In the horizontal retracing period of the horizontal scanning period, since the 6n number of the sampling switches 151 is turned on at the same time, all the data lines 114 are conductive to the image signal lines 171. Meanwhile, in the horizontal valid scanning period of each horizontal scanning period, a total of the six sampling switches 151 in each of the blocks Bj is turned on every block Bj. As a result, the data lines 114 are conductive to the image signal lines 171 every block Bj. In the embodiment, in the horizontal valid scanning period, the sampling signals S1, S2 . . . , Sn sequentially become an active level, as shown in FIG. 4. Resultantly, the blocks B1, B2 . . . , Bn are sequentially selected along a direction (hereinafter, referred to as block selection direction), which is oriented from the left to the right of FIG. 2.

The operation of the selector 340 and the precharge voltage generation circuit 350 shown in FIG. 1 will be below described in detail. The selector 340 can select any one of the image signals Vd1 to Vd6 output from the image signal output circuit 310 and the precharge voltages Vpre(1) to Vpre(6) output from the precharge voltage generation circuit 350, according to a level of the signal NRG, and then supplies the selected signal to the display panel 100. This will be described below in more detail. If the signal NRG is at an active level (H level), the selector 340 selects the precharge voltages Vpre(1) to Vpre(6), and outputs the selected signals to the image signal lines 171, respectively, as the signals Vid1 to Vid6. On the other hand, if the signal NRG is at an inactive level (L level), the selector 340 selects the image signals Vd1 to Vd6, and outputs them to the image signal lines 171, respectively, as the signals Vid1 to Vid6. As described above, the signal NRG is a signal that is kept to an inactive level in the horizontal valid scanning period, while shifting to an active level in the horizontal retracing period. Thus, voltages of the signals Vid1 to Vid6 applied to the respective image signal lines 171 become the precharge voltages Vpre(1) to Vpre(6) in the horizontal retracing period. In the horizontal valid scanning period, however, the voltages of the signals Vid1 to Vid6 become voltages of the image signals Vd1 to Vd6.

For example, as shown in FIG. 4, the voltage of the signal Vid1 applied to the first image signal line 171 is kept to the precharge voltage Vpre(1) in the horizontal retracing period, whereas it is kept to a voltage of the image signal Vd1 in the horizontal valid scanning period. Therefore, in the horizontal valid scanning period, if the six sampling switches 151 each corresponding to the blocks Bj are turned on, the voltages of the image signals Vd1 to Vd6 can be applied to the six pixel electrodes 118, which are located at the intersections of the scanning lines 112 of an i-th row and the six data lines 114 that belong to the block Bj. This process is repeatedly performed on all the blocks B1 to Bn in a corresponding horizontal valid scanning period.

Meanwhile, in the horizontal retracing period, if the 6n number of all the sampling switches 151 are turned on, the 6n number of all the data lines 114 are conductive to the image signal lines 171, and are thus charged with the precharge voltages Vpre(1) to Vpre(6). If this is expressed by way of a natural number k, a k-th data line 114 from the left side of the six data lines 114 that belong to each of the blocks Bj are charged with the precharge voltage Vpre(k). Further, in the horizontal retracing period where each of the data lines 114 is precharged, the precharge voltages Vpre(1) to Vpre(6) are not applied to the pixel electrodes 118 because the scanning signal Gi is at an inactive level. As such, since the data lines 114 are charged with the precharge voltages Vpre(1) to Vpre(6) before the image signals Vd1 to Vd6 are applied to the pixel electrodes 118, respectively, it is thus possible to reduce the time taken to shift voltages of the data lines 114 to voltages of the image signals Vd1 to Vd6 in the horizontal valid scanning period. Accordingly, even if the time of the horizontal valid scanning period is relatively short, a voltage of each of the pixel electrodes 118 can surely reach a voltage of each of the image signals Vd1 to Vd6.

Meanwhile, the precharge voltage generation circuit 350 is a circuit that generates the precharge voltages Vpre(1) to Vpre(6), and outputs them to the selector 340. The precharge voltage generation circuit 350 alternately switches a voltage value of a precharge voltage Vpre(k) from one side of a voltage +Vk of the positive polarity and a voltage −Vk of the negative polarity to the other side thereof, and vice versa with respect to the voltage Vc in each horizontal scanning period. Each of precharge voltages Vpre(k) has the same polarity as that of the image signal Vdk.

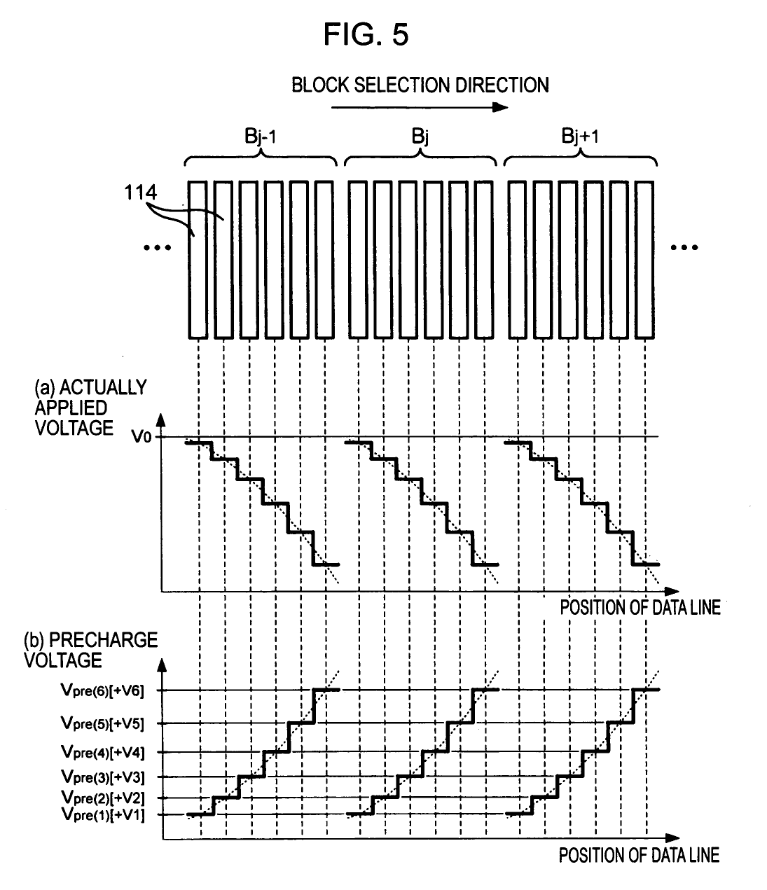

If all the data lines 114 are to be charged with a common precharge voltage, however, there occurs a case in which display unevenness is generated because gray-scale levels that are actually displayed are different in an X direction when the common gray-scale level is displayed in all the pixels 110. For example, FIG. 5(a) is a view illustrating voltages of the image signals Vd1 to Vd6 (i.e., voltages applied to the respective data lines 114), which are actually applied to the pixel electrodes 118, respectively, in the case in which the image signals Vd1 to Vd6 applied to all the pixels 110 are used as a common voltage (i.e., if all the pixels 110 are to be displayed as the common gray-scale level) in the construction in which all the data lines 114 are charged with the common precharge voltage (or, a construction in which no data lines 114 are precharged).

In FIG. 5(a), it is assumed that a difference between an actually applied voltage and an original voltage V0 depending upon a desired gray-scale level becomes greater at a data line 114, which is located in the downstream of a block selection direction, among the six data lines 114 that belong to each of the blocks Bj (i.e., a case in which though the voltage V0 must be applied to all the data lines 114 of each of the blocks Bj, an applied voltage becomes lower at the data line 114 located in the downstream of the block selection direction). In this case, if the display panel 100 is in normally white mode, a gray-scale level becomes higher (lighter) at the pixel 110, which is located in the downstream of the block selection direction, in each of the blocks Bj. If the display panel 100 is in normally black mode, a gray-scale level becomes lower (darker) at a pixel 110, which is located in the downstream of the block selection direction, in each of the blocks Bj. Thus, the gray-scale level of each of the pixels 110 becomes irregular every block Bj along the X direction, which may result in display unevenness.

The cause of the variation in the voltages applied to the data lines 114 can include variation in electrical properties every image signal line 171 (e.g., variation in resistance values due to a difference in wire length), variation in voltages between the image signal lines 171, which is caused due to a difference in characteristics among the D/A converters in the D/A converter group 314, or capacitive coupling among neighboring data lines 114. That is, for example, since the sixth data line 114 (a data line 114 located at the downstream end of block selection direction) that belong to the block Bj and a data line 114 (particularly, the first data line 114) that belongs to the block Bj+1 adjacent to the block Bj are capacitively coupled, the image signal Vd6, which is applied to the sixth data line 114 that belongs to the block Bj in a given horizontal valid scanning period, varies depending upon the image signals Vd1 to Vd6 each applied to the data lines 114 of the block Bj+1 in the horizontal scanning period. As a result, if it is desired to display a common gray-scale level in all the pixels 110, there occurs a case in which the pixel 110 connected to the sixth data line 114 that belongs to each of the blocks Bj can be displayed as a gray-scale level different from those of other pixels 110.

For example, if the display panel 100 is in normally white mode, the pixel 110 corresponding to the sixth data line 114 can be displayed with a gray-scale level lower than those of other pixels 110 (lighter gray-scale level). On the other hand, if the display panel 100 is in normally black mode, the pixel 110 corresponding to the sixth data line 114 is displayed with a gray-scale level higher than those of other pixels 110 (darker gray-scale level). Further, although the sixth data line 114 that belongs to the block Bj has been described as an example, the same problem can occur in other data lines 114. Thus, voltages that are actually applied to the data lines 114 become irregular due to a variety of factors including variation in voltages, which is caused because of such capacitive coupling, as shown in FIG. 5A.

In order to solve this problem, in the exemplary embodiment, the precharge voltage generation circuit 350 is constructed to independently control a voltage value ±Vk of each of the precharge voltages Vpre(1) to Vpre(6). This will be below described in more detail. The precharge voltage generation circuit 350 controls a voltage value ±Vk of each of the precharge voltages Vpre(1) to Vpre(6) in an independent manner in such a way that a difference between a predetermined voltage that has to be applied to the data lines 114 and a voltage that is actually applied becomes almost the same in the entire data lines 114 of each of the blocks Bj.

For example, in FIG. 5(a), each of the precharge voltages Vpre(1) to Vpre(6) is selected so that an absolute value of the voltage value ±Vk is higher in the precharge voltage Vpre(k) of the data line 114, which is located in the downstream of the block selection direction of each of the blocks Bj, as shown in FIG. 5(b). In other words, the precharge voltage Vpre(k) for charging a k-th data line 114 of each of the blocks Bj has an absolute value of a voltage value, which is higher than the precharge voltage Vpre(k−1) of a (k−1)th data line 114 that is located toward the upstream of the block selection direction. Meanwhile, in FIG. 5(b), only the voltage value +Vk of the positive polarity of each of the precharge voltages Vpre(k) is shown.

A detailed voltage value(±Vk) of each of the precharge voltages Vpre(1) to Vpre(6) that are generated by the precharge voltage generation circuit 350 is designated by the control circuit 200. The control circuit 200 designates a voltage value of each of the precharge voltages Vpre(1) to Vpre(6) in the precharge voltage generation circuit 350, according to manipulation, which is made to a manipulator (not shown) by a user. Therefore, the user can properly manipulate the manipulator, while actually confirming the image displayed on the display region 100a, whereby display unevenness in the X direction can be effectively reduced.

As described above, in the embodiment, since the voltage value ±Vk of the precharge voltage Vpre(k) is controlled every data line 114 of each of the blocks Bj, variations in voltages actually applied to the data lines 114 can be corrected through control of the precharge voltage Vpre(k). It is thus possible to obviate display unevenness. Further, in accordance with this construction, a process of correcting a difference in voltages applied to the data lines 114 needs not to be performed on the image signals Vd1 to Vd6. This prevents the construction of the image signal output circuit 310 from becoming complicated, and the circuit from becoming bulky.

It is to be understood that the aforementioned embodiment can be modified in various ways. The following examples of modifications can be considered. Furthermore, the following modifications can be combined in a proper manner.

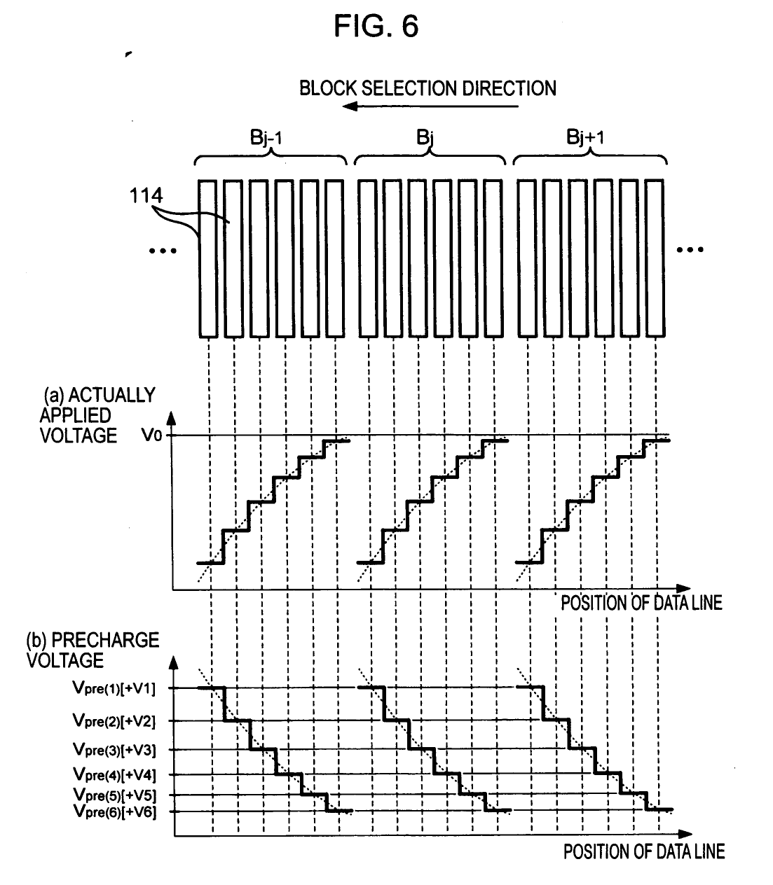

In the above-described exemplary embodiment, a case in which each of the blocks Bj is selected from the left to the right in FIG. 2 in the horizontal valid scanning period has been described. On the contrary, there will be a case in which each of the blocks Bj is selected in the order of the blocks Bn, B(n−1) . . . , B2, B1 from the right to the left in FIG. 2. In this case, if all the data lines 114 are charged with a common precharge voltage (or none of the data lines 114 is precharged), the relation between a location of each of the data lines 114 in each of the blocks Bj and a voltage actually applied to each of the data lines 114 is the reversion of the relation shown in FIG. 5(a), as shown in FIG. 6(a). In other words, a voltage, which is applied to a first data line 114, which is located on the leftmost side, among the six data lines 114 that belong to the block Bj, is the lowest, and a voltage applied to the data lines 114 that belong to the block Bj on the right side increases. In this case, as shown in FIG. 6(b), it is preferred that the voltage value ±Vk of each of the precharge voltages Vpre(k) is selected in such a way that an absolute value of a voltage value ±V1 of the precharge voltage Vpre(1) for precharging the first data line 114 of each block Bj becomes the highest and an absolute value of a voltage value ±V6 of the precharge voltage Vpre(6) of the sixth data line 114 that belongs to the block Bj becomes the lowest. That is, it is considered that a difference between a predetermined voltage V0 and a voltage actually applied to each of the data lines 114 rises in a data line 114, which is located in the downstream of the block selection direction, in each block Bj.

In view of this, it will be thus preferred that a voltage value of each of the precharge voltages Vpre(1) to Vpre(6) is selected so that an absolute value of the voltage value is higher in the precharge voltage Vpre(k) of a data line 114 that is located in the downstream of the block selection direction. Further, the precharge voltage generation circuit 350 can be constructed to designate a block selection direction through the data line driving circuit 140, and can also be constructed to select the small and large of each of the precharge voltages Vpre(k), as in Fig. (b), or the small and large of each of the precharge voltages Vpre(k), as in Fig. (b), depending upon the designated direction.

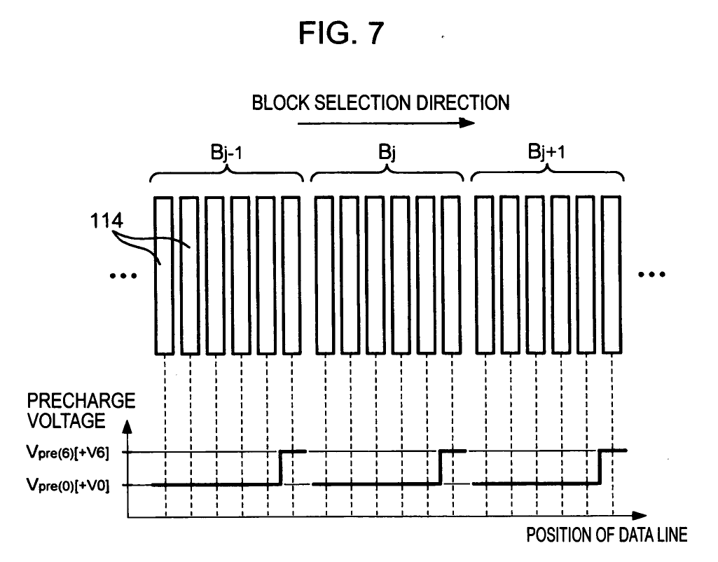

In the aforementioned embodiment, a case in which a voltage applied to a data line 114, which is located in the downstream of the block selection direction, among the data lines 114 that belong to each block Bj, is significantly different from a desired voltage V0 has been described as an example. If only capacitive coupling among neighboring data lines 114 is considered, however, a case in which only a voltage applied to a data line 114, which is located in the most downstream of the block selection direction, among the data lines 114 that belong to each block Bj is different from a desired voltage V0 (voltages actually applied to the remaining five data lines 114 are approximately the same as the desired voltage V0) can be considered. In this case, as shown in FIG. 7, the data line 114 (i.e., the sixth data line 114) located in the most downstream of the block selection direction is precharged with the precharge voltage Vpre(6), whereas the remaining five data lines 114 can be commonly precharged with the precharge voltage Vpre(0), which has an absolute value lower than that of the precharge voltage Vpre(6).

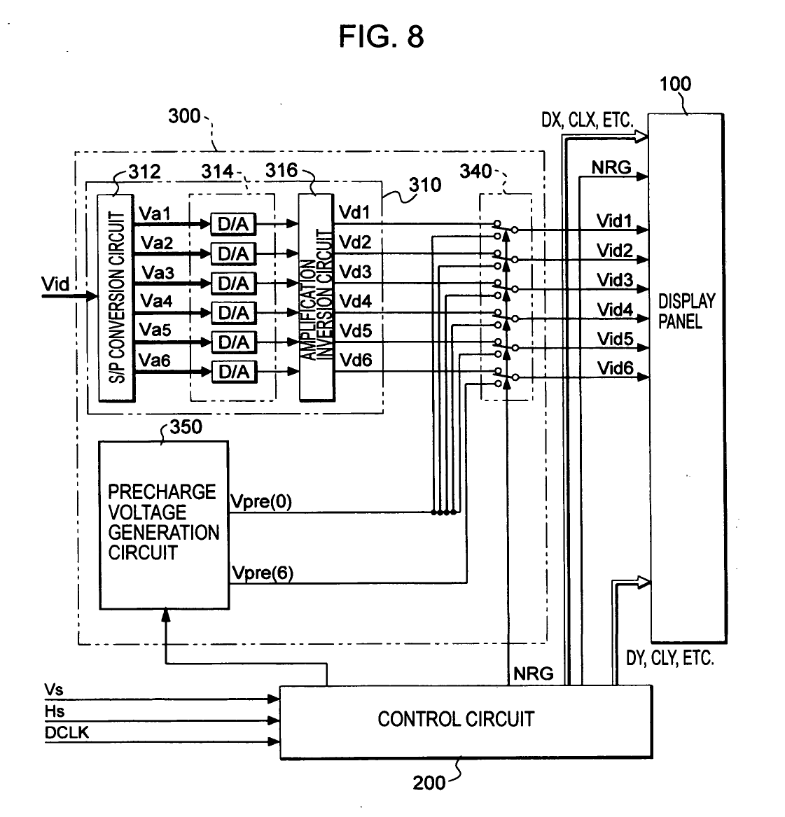

In this exemplary construction, as shown in FIG. 8, the precharge voltage generation circuit 350 generates only two kinds of voltages such as the precharge voltages Vpre(0) and Vpre(6), whereas the selector 340 selects one of the image signals Vd1 to Vd5 and the precharge voltage Vpre(0), and one of the image signal Vd6 and the precharge voltage Vpre(6), according to the signal NRG As such, it is not necessarily required that a total number of the precharge voltages Vpre(k) that is generated by the precharge voltage generation circuit 350 and a total number of the image signal lines 171 be the same. For instance, it will be enough if a plurality of precharge voltages having different voltage values is generated by the precharge voltage generation circuit 350, wherein the precharge voltages are applied to the N the image signal lines 171 corresponding to the channel number, respectively.

In the above-described exemplary embodiment, the construction in which the respective data lines 114 are precharged in the entire horizontal retracing period has been described as an example. However, a construction in which each of the data lines 114 is precharged in some of the horizontal retracing period can be adopted. That is, in the invention, a construction in which precharging of each of the data lines 114 is performed in a period (i.e., precharge period in the invention), which is not overlapped with the period where any one of the scanning lines 112 is selected and the image signal Vd is thus applied to each of the pixels 110 (horizontal valid scanning period in the aforementioned embodiment), on a time axis, will suffice. In this connection, it is not a matter whether the precharge period and the horizontal retracing period correspond to each other.

In the above-mentioned embodiment, it has been described that the channel number N of the image signal Vd is “6”, but it can be arbitrarily set. Accordingly, it should be understood that a total number of the precharge voltages Vpre(k) that are generated by the precharge voltage generation circuit 350 or a total number of the image signal lines 171 are not limited to “6”, but can properly vary depending upon the channel number N of the image signal Vd.

The circuits described in the aforementioned embodiment, such as the data line driving circuit 140, the scanning line driving circuit 130, the image processing circuit 300 and the control circuit 200, can be integrally formed on, e.g., one IC chip, or can be formed separately. This is also true of circuits such as the image signal output circuit 310, the precharge voltage generation circuit 350 and the selector 340, which constitute the image processing circuit 300. It is, however, not a matter whether these circuits are integrally formed or separately formed.

In the above-mentioned embodiment, the liquid crystal device has been described as an example. It is, however, to be understood that the invention can be applied to even devices using an electro-optical material other than liquid crystal. The electro-optical material is a material whose optical properties, such as transmittance or brightness, vary depending upon application of electrical signals (current signals or voltage signals). For example, the invention can be applied to various electro-optical devices such as display devices wherein OLED devices such as organic EL or light-emitting polymer are used as the electro-optical material, electrophoretic migration devices wherein microcapsule including white colored liquid and particles dispersed in the liquid is used as the electro-optical material, twist ball displays wherein twist balls where different colors are coated in regions having different polarity are used as the electro-optical material, toner displays using black toner as the electro-optical material, and plasma display panels wherein a high pressure gas such as helium or neon is used as the electro-optical material, in the same manner as the aforementioned embodiments.

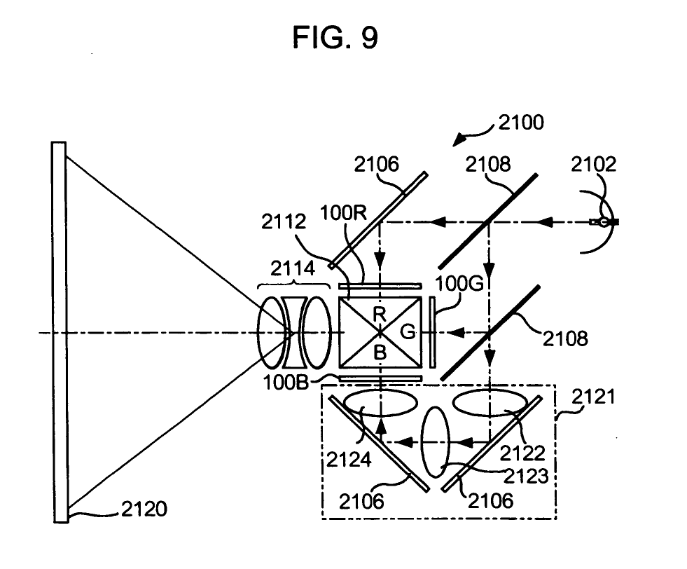

Next, an exemplary projector using the liquid crystal device according to the above embodiment as a light valve will now be described as an example of an electronic device using the electro-optical device according to the invention. FIG. 9 is a plan view illustrating the configuration of the projector. Referring to FIG. 9, a lamp unit 2102 including a white light source such as a halogen lamp is disposed within the projector 2100. Light projected from the lamp unit 2102 is separated into three primary colors of R (red), G (green) and B (blue) through three mirrors 2106 and two dichroic mirrors 2108 in the lamp unit 2102, and are then sent to light valves 100R, 100G and 100B corresponding to the three primary colors, respectively. In this case, since the light of the B color has a longer optical path than those of the R and G colors, it is sent to a relay lens system 2121 having an incidence lens 2122, a relay lens 2123 and an exit lens 2124 in order to prevent its loss.

In this case, the construction of the light valves 100R, 100G and 100B is the same as that of the liquid crystal device in the above embodiment. The light valves 100R, 100G and 100B are driven according to image signals, which correspond to the R, G and B colors, respectively, and are supplied from the image processing circuit 300. Light, which is modulated by the light valves 100R, 100G and 100B, respectively, is incident on a dichroic prism 2112 in three directions. In the dichroic prism 2112, the light of the R and B colors is refracted at an angle of 90 degrees, whereas the light of the G color goes straight ahead. Thus, after images of the respective colors are composed, a color image is projected onto a screen 2120 by a projection lens 2114.

Furthermore, as the light corresponding to the primary colors of R, G and B is incident on the light valves 100R, 100G and 100B by the dichroic mirror 2108, it is not necessary to provide a color filter. In addition, the images projected by the light valves 100R and 100B are projected after being reflected from the dichroic prism 2112, whereas the light projected from the light valve 100G is projected as it is. Accordingly, the projector is constructed to display an image that is inverted right and left in such a manner that a horizontal scan direction by the light valves 100R and 100B is in an opposite direction to a horizontal scan direction by the light valve 100G.

Moreover, electronic devices in which the electro-optical device according to the invention can be employed may include devices having a mobile phone, a mobile personal computer, a liquid crystal TV, a view finder type (or monitor direct view type) video recorder, a car navigation system, a pager, a personal digital assistant (PDA), an electronic calculator, a word processor, a workstation, a video phone, a POS terminal and a touch panel, as well as the projector shown in FIG. 9.

While this invention has been described in conjunction with the specific embodiments thereof, it is evident that many alternatives, modifications, and variations will be apparent to those skilled in the art. Accordingly, preferred embodiments of the invention as set forth herein are intended to be illustrative, not limiting. There are changes that may be made without departing from the spirit and scope of the invention.

1. An electro-optical device, comprising:
a plurality of pixels disposed at intersections of a plurality of scanning lines and a plurality of data lines that are divided into blocks of N data lines (N being a natural number greater than 2), and the pixels respectively having gray-scale levels corresponding to voltages applied to the data lines when the scanning lines are selected;
a scanning line driving circuit that selects the scanning lines in selection periods that are separated by a time gap;
a precharge voltage generation circuit that generates a plurality of precharge voltages to precharge the plurality of data lines, the precharge voltage generation circuit generating the precharge voltages so that a precharge voltage corresponding to one of N data lines belonging to each block is different from precharge voltages corresponding to other data lines in each block;
N image signal lines that respectively correspond to the data lines in each block, the image signal lines applying voltages corresponding to gray-scale levels of pixels corresponding to the data lines in each block in the selection period, and at the same time, applying the plurality of precharge voltages generated by the precharge voltage generation circuit in precharge periods other than the selection period; and
a data line driving circuit that applies the voltages applied to the image signal lines to the data lines in each block in the selection period, and at the same time applies the voltages to the data lines in the precharge period.

2. The electro-optical device according to claim 1,
the data line driving circuit sequentially selecting the plurality of blocks in the order of their arrangement in the selection period, and at the same time, supplying the voltages applied to the image signal lines to the data lines of the selected blocks; and
the precharge voltage generation circuit generating the precharge voltages so that the precharge voltage of a data line that is located at a downstream end of a direction in which the blocks are selected, among the N data lines belonging to each block, is higher than the precharge voltages of other data lines in each block.

3. The electro-optical device according to claim 1,
the precharge voltage generating circuit generates voltages having different values as N precharge voltages corresponding to the data lines that belong to each block.

4. The electro-optical device according to claim 3,
the data line driving circuit sequentially selecting the plurality of blocks in the order of their arrangement in the selection period, and at the same time, supplying the voltages applied to the image signal lines to the data lines of the selected blocks; and
the precharge voltage generation circuit generating the precharge voltages so that the precharge voltage of a data line that is located at a downstream end of a direction in which the blocks are selected, among the N data lines belonging to each block, is higher than the precharge voltages of other data lines in each block.

5. An electronic device having the electro-optical device according to claim 1 as a display device.

6. A method of precharging a plurality of data lines before a plurality of scanning lines is selected in an electro-optical device, in which a plurality of pixels are disposed at intersections of the plurality of the scanning lines and the plurality of the data lines, that are divided into blocks of N data lines (N being a natural number greater than 2), and the plurality of pixels have brightnesses corresponding to voltages applied to the data lines when the scanning lines are selected in selection periods separated by a time gap, the method comprising:
generating precharge voltages, in which the precharge voltage corresponding to one of N data lines belonging to each block is different from the precharge voltages corresponding to other data lines in each block;
applying voltages corresponding to gray-scale levels of pixels corresponding to the data lines in each block to N image signal lines corresponding to the data lines in each block, on a block basis, in the selection period, and at the same time applying the plurality of precharge voltages in precharge periods other than the selection period; and
applying the voltage applied to the image signal lines to the data lines in each block in the selection period, and at the same time applying the voltages to the data lines in the precharge period.

7. An image processing circuit for an electro-optical device, comprising:
a plurality of pixels disposed at intersections of a plurality of scanning lines and a plurality of data lines which are divided into blocks of N data lines (N being a natural number greater than 2), and that have gray-scale levels corresponding to voltages applied to the data lines when the scanning lines are selected;
a scanning line driving circuit that selects the scanning lines in selection periods separated by a time gap;
N image signal lines that respectively correspond to the data lines in each block;
a data line driving circuit that supplies voltages applied to the image signal lines to the data lines on a block basis in the selection period, and at the same time applies the voltages to the data lines in precharge periods that are different from the selection period;
an image signal output circuit that generates N image signals having different voltages corresponding to gray-scale levels of pixels corresponding to the data lines in each block on a block basis;
a precharge voltage generation circuit that generates a plurality of precharge voltages to precharge the plurality of data lines, the precharge voltage generation circuit generating the precharge voltages so that a precharge voltage corresponding to one of N data lines belonging to each block is different from precharge voltages corresponding to the other data lines in each block; and
a selection circuit that supplies the image signals generated by the image signal output circuit to the image signal lines in the selection period, and at the same time supplies the precharge voltages generated by the precharge voltage generation circuit to the image signal lines corresponding to the data lines precharged with the precharge voltages in the precharge period.
